(19) United States
(12) Patent Application Publication
(10) Pub. No.: US 2011/0075299 A1
(43) Pub. Date: Mar. 31, 2011

(54) MAGNETIC WRITE HEADS FOR HARD DISK DRIVES AND METHOD OF FORMING SAME

(76) Inventors: Trevor W. Olson, San Jose, CA (US); Aron Pentek, San Jose, CA (US); Thomas J. A. Roucoux, San Jose, CA (US)

(21) Appl. No.: 12/569,962

(22) Filed: Sep. 30, 2009

(51) Int. Cl. G11B 5/60; G11B 5/127; C23C 14/34

(52) U.S. Cl. 360/235.4; 427/130; 204/192.15; G9B/5.229

(57) ABSTRACT

Embodiments provide a write pole and a magnetic shield for write heads. The write pole includes a trailing step, while the magnetic shield includes a slanted bump. The slanted bump and the trailing step provides maximize magnetic flux for writing to a magnetic media such as a magnetic storage disk in a hard disk drive, while avoiding saturation. One embodiment of a method for forming the write pole includes depositing non-magnetic gap material on the write pole and trailing step. An ion beam milling process is used to form a taper in the non-magnetic gap material. The magnetic shield is then deposited on the taper, forming the slanted bump of the shield.

### BACKGROUND OF THE INVENTION

1. Field of the Invention

Embodiments of the present invention generally relate to write heads for hard disk drives and in particular to magnetic shields of write heads used for perpendicular recording on a magnetic disk.

2. Description of the Related Art

There has been increasing progress in the field of magnetic disk storage system technology in recent years. Such success has made storage systems an important component of modern computers. Some of the most important customer attributes of any storage system are the cost per megabyte, data rate, and access time. In order to obtain the relatively low cost of magnetic disk storage systems compared to solid state memory, the customer must accept the less desirable features of this technology, which include a relatively slow response, high power consumption, noise, and the poorer reliability attributes associated with any mechanical system. On the other hand, magnetic storage systems have always been nonvolatile; i.e., no power is required to preserve the data, an attribute which in semiconductor devices often requires compromises in processing complexity, power-supply requirements, writing data rate, or cost. Improvements in areal density (the amount of information that can be placed within a given area on a disk drive), have been the chief driving force behind the historic improvement in storage cost. In fact, the areal density of magnetic disk storage systems continues to increase. As the magnetic particles that make up recorded data on a magnetic disk become ever smaller, technical difficulties in writing and reading such small bits occur.

Perpendicular recording is one alternative to increase areal densities when compared with longitudinal recording. In recent years, the increased demand for higher data rate and areal density has driven the perpendicular head design to scale toward smaller dimensions and the need for constant exploration of new head designs, materials, and practical fabrication methods. Some of the problems encountered with perpendicular recording are side writing and side erasure, to adjacent tracks on the disk. These problems occur from leakage and fringing of the magnetic flux from the magnetic write head. To minimize these effects, one approach is to provide either a trailing or wrap-around shield on the magnetic write head. These shields allow effective magnetic flux to be provided for writing to the disk, while avoiding leakage and fringing that can lead to the above-described problems. As the areal density of the disks increases, however, the ability of existing shields to achieve the desired results decreases.

### SUMMARY OF THE INVENTION

The present invention, in a first embodiment, is a magnetic write head for a hard disk drive. A magnetic write head for a hard disk drive. The magnetic head includes an air bearing surface (ABS), a magnetic write pole having an end that defines part of the ABS, the magnetic write pole including a trailing step, such that the write pole has a first thickness at the end that defines part of the ABS and a second thickness in the region of the trailing step, the second thickness being greater than the first thickness and a layer of non-magnetic gap material disposed on the magnetic write pole, the layer of non-magnetic gap material including a taper defined by an increasing thickness of the layer of non-magnetic gap material from a third thickness at a first distance from the ABS, to a fourth thickness at a second distance from the ABS, the second distance being greater than the first distance and the fourth thickness being greater than the third thickness and a magnetic shield disposed on the layer of non-magnetic gap material.

In a further embodiment, the invention is a hard disk drive having a magnetic storage disk and a magnetic write head for writing data to the disc drive. The magnetic write head includes an air bearing surface (ABS), a magnetic write pole having an end that defines part of the ABS, the magnetic write pole including a trailing step, such that the write pole has a first thickness at the end that defines part of the ABS and a second thickness in the region of the trailing step, the second thickness being greater than the first thickness and a layer of non-magnetic gap material disposed on the magnetic write pole, the layer of non-magnetic gap material including a taper defined by an increasing thickness of the layer of non-magnetic gap material from a third thickness at a first distance from the ABS, to a fourth thickness at a second distance from the ABS, the second distance being greater than the first distance and the fourth thickness being greater than the third thickness and a magnetic shield disposed on the layer of non-magnetic gap material.

In another embodiment the invention is a method of forming a magnetic write head. The method includes providing a substrate, the substrate having a first layer of magnetic material for forming a magnetic pole of the write head, and having a surface, depositing and patterning a resist layer on the surface of the substrate, such that a first part of the surface is covered by the resist layer and a second part of the surface is exposed, depositing a second layer of magnetic material on the exposed part of the surface of the first layer, depositing a third layer of non-magnetic material on the second layer of magnetic material, removing the resist layer, depositing a fourth endpoint layer of on the third layer and on an exposed portion of the first layer, depositing a fifth non-magnetic layer on the fourth layer, selectively removing part of the fifth layer to form a taper in the fifth layer, such that the fifth layer increases in thickness from a first thickness at a first distance from the ABS, to a second thickness at a second distance from the ABS, where the second thickness is greater than the first thickness and the second distance is greater than the first distance, depositing a sixth layer of non-magnetic material on a remainder of the fifth layer and depositing a seventh layer of magnetic material on the sixth layer to form a magnetic shield of the write head.

In yet a further embodiment, the invention is another method of forming a magnetic write head. The method includes providing a magnetic write pole having an end that defines part of an ABS, forming a trailing step on the write pole to produce a stepped write pole, such that the stepped write pole has a first thickness at the end that defines part of the ABS and a second thickness in the region of the trailing step, the second thickness being greater than the first thickness, forming a layer of non-magnetic gap material on the stepped write pole, the layer of non-magnetic gap material including a taper defined by an increasing thickness of the layer of non-magnetic gap material from a third thickness at a first distance from the ABS, to a fourth thickness at a second distance from the ABS, the second distance being greater than the first distance and the fourth thickness being greater than the third thickness and forming a magnetic shield on the layer of non-magnetic gap material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows an exemplary disk drive having a magnetic disk, and magnetic read/write head mounted on an actuator, according to one embodiment of the invention.

FIG. 2A is a side view of the read/write head and magnetic disk of the disk drive of FIG. 1, according to one embodiment of the invention.

FIG. 2B is an enlarged side view of a portion of the read/write head of FIG. 2A, according to one embodiment of the invention.

FIG. 2C is a enlarged top view of a portion of the read/write head of FIG. 2A, according to a further embodiment of the invention.

FIGS. 3A-3G are side views showing various stages of producing a magnetic write head, according to one embodiment of the invention.

FIG. 4 is a cross section of the structure of FIG. 3G taken through section line 4-4.

FIG. 5 is a cross section of the structure of FIG. 3G taken through section line 5-5.

FIG. 6 is a cross section of the structure of FIG. 3G taken through section line 6-6.

### DETAILED DESCRIPTION

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Embodiments of the present invention are related to magnetic write heads for hard disk drives. More particularly, the invention is related to the write pole and magnetic shield of a magnetic write head. In some cases, embodiments of the present invention may mitigate magnetic flux leakage and fringing and the problems caused thereby, in magnetic write heads for hard disk drives. While embodiments of the invention are particularly suitable for use in magnetic disk hard drives, this use should not be considered limiting as the magnetic write head of the invention could be used to write to any type of magnetic media, particularly (but not exclusively) where magnetic leakage and fringing is an issue. The advent of perpendicular magnetic recording, (PMR), while providing significantly higher storage density than longitudinal recording, has introduced its own set of challenges. One of these challenges is the need to suppress stray fields from the perpendicular write pole, due to the high writing current required in perpendicular recording. One method of suppressing stray magnetic fields, is through the use of magnetic shields at the trailing end of the read/write head. The shield is separated from the write pole by a shield gap formed of non-magnetic material. The shield gap has a portion of reduced thickness adjacent the ABS and forms a shield gap throat. In the region of the shield gap throat the distance between the magnetic shield and the write pole is reduced. The height of the shield gap throat, from the ABS to the point where the gap starts to increase in thickness is known as the throat height. For high area density PMR, the shield throat height must be relatively small. However, the small throat height tends to cause saturation. Embodiments of the present invention provide a tapered non-magnetic bump in front of (closer to the ABS) a trailing step of the write pole. The tapered bump in the gap material provides a relatively small throat height, while avoiding saturation of the shield.

Two common types of magnetic shields for perpendicular write head poles are the trailing shield and the wrap-around shield. A trailing shield is predominantly located on the trailing end of the read/write head, while wrap-around shields provide additional shielding by wrapping around the write pole and covering the sides of the write pole as well as the trailing end. The wrap-around shield is the most efficient type of shield for stray field suppression. Both types of shields benefit from the tapered non-magnetic bump in front of the stepped write pole of the invention.

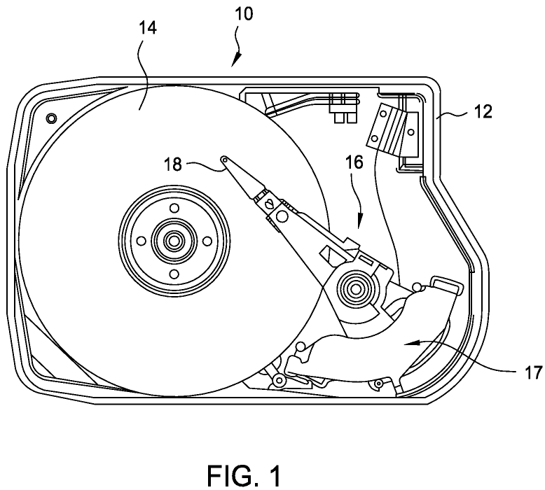

FIG. 1 shows one embodiment of a magnetic hard disk drive 10 that includes a housing 12 within which a magnetic disk 14 is fixed to a spindle motor (SPM) by a clamp. The SPM drives the magnetic disk 14 to spin at a certain speed. A head slider 18 accesses a recording area of the magnetic disk 14. The head slider 18 has a head element section and a slider to which the head element section is fixed. The head slider 18 is provided with a fly-height control which adjusts the flying height of the head above the magnetic disk 14. An actuator 16 carries the head slider 18. In FIG. 1, the actuator 16 is pivotally held by a pivot shaft, and is pivoted around the pivot shaft by the drive force of a voice coil motor (VCM) 17 as a drive mechanism. The actuator 16 is pivoted in a radial direction of the magnetic disk 14 to move the head slider 18 to a desired position. Due to the viscosity of air between the spinning magnetic disk 14 and the head slider's air bearing surface (ABS) facing the magnetic disk 14, a pressure acts on the head slider 18. The head slider 18 flies low above the magnetic disk 14 as a result of this pressure balancing between the air and the force applied by the actuator 16 toward the magnetic disk 14.

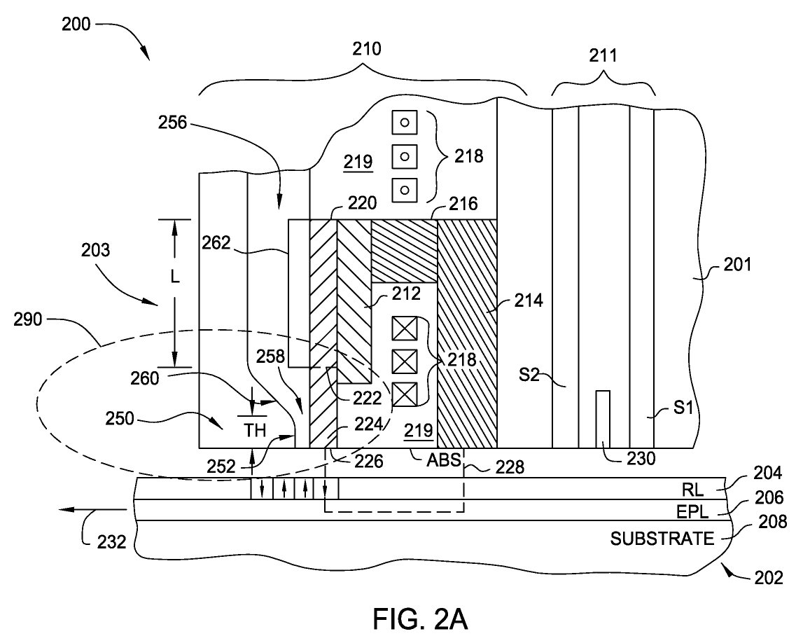

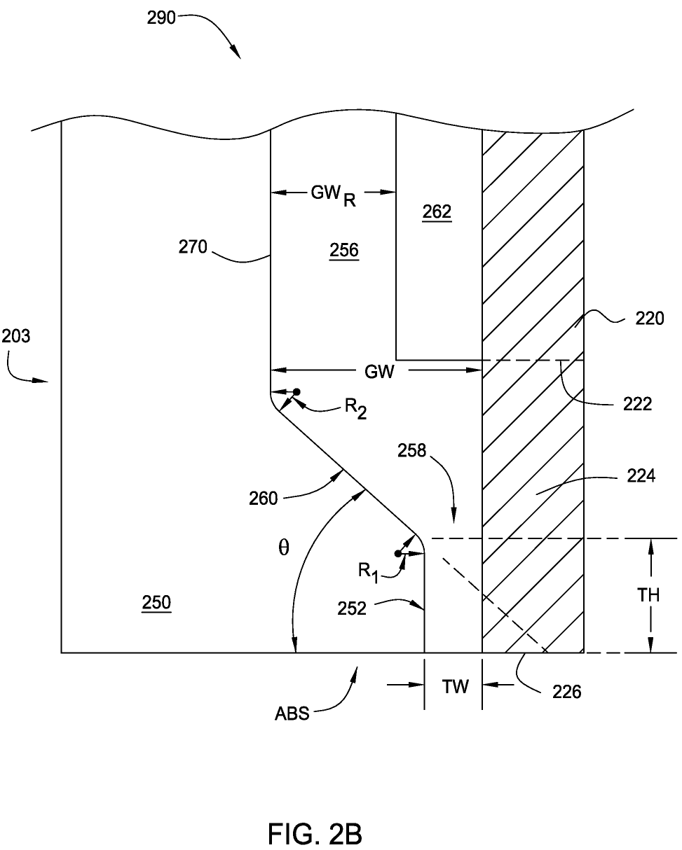

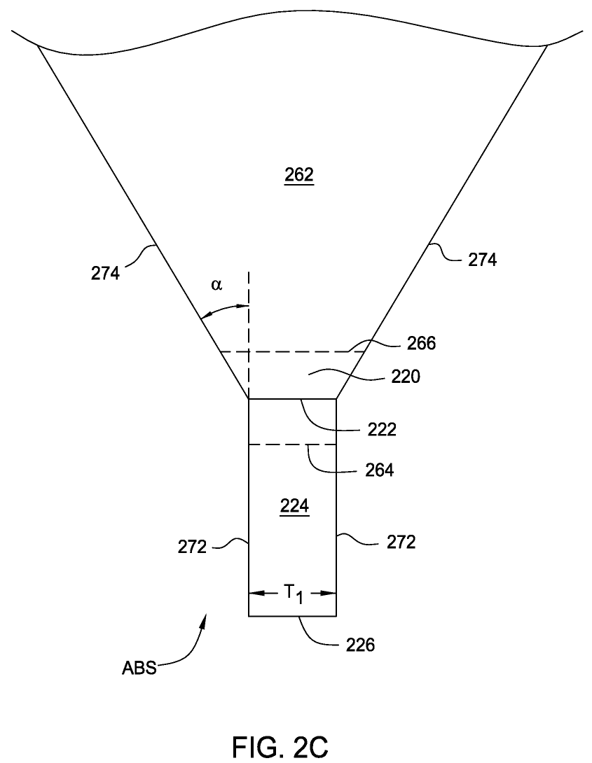

FIG. 2A is a fragmented, cross-sectional side view through the center of an embodiment of a read/write head 200 mounted on a slider 201 and facing magnetic disk 202. In one embodiment, the slider 201 is the head slider 18 of FIG. 1 and magnetic disk 202 is the magnetic disk 14 of FIG. 1. In some embodiments, the magnetic disk 202 may be a “dual-layer” medium that includes a perpendicular magnetic data recording layer (RL) 204 on a “soft” or relatively low-coercivity magnetically permeable underlayer (EBL) 206 formed on a disk substrate 208. The read/write head 200 includes an air bearing surface (ABS), a magnetic write head 210 and a magnetic read head 211, and is mounted such that its ABS is facing the magnetic disk 202. In FIG. 2A, the disk 202 moves past the write head 210 in the direction indicated by the arrow 232, so the portion of slider 201 that supports the read/write head 200 is often called the slider “trailing” end 203.

In some embodiments, the magnetic read head 211 is a magnetoresistive (MR) read head that includes an MR sensing element 230 located between MR shields S1 and S2. The RL 204 is illustrated with perpendicularly recorded or magnetized regions, with adjacent regions having magnetization directions, as represented by the arrows located in the RL 204. The magnetic fields of the adjacent magnetized regions are detectable by the MR sensing element 230 as the recorded bits.

The write head 210 includes a magnetic circuit made up of a main pole 212, a flux return pole 214, and a yoke 216 connecting the main pole 212 and the flux return pole 214. The write head 210 also includes a thin film coil 218 shown in section embedded in non-magnetic material 219 and wrapped around yoke 216. A write pole 220 (also referred to herein as “WP 220”) is magnetically connected to the main pole 212 and has an end 226 that defines part of the ABS of the magnetic write head 210 facing the outer surface of disk 202. In some embodiments, write pole 220 is a flared write pole and includes a flare point 222 and a pole tip 224 that includes an end 226 that defines part of the ABS. In flared write pole embodiments, the width of the write pole 220 in a first direction (into and out of the page in FIG. 2A), increases from a first width at the flare point 222 to greater widths away from the ABS, as is shown in FIG. 2C. The flare may extend the entire height of write pole 220 (i.e., from the end 226 of the write pole 220 to the top of the write pole 220), or may only extend from the flare point 222, as shown in FIG. 2A. In one embodiment the distance between the flare point 222 and the ABS is between about 30 nm and about 150 nm. In some embodiments, the WP 220 includes a trailing step 262 of magnetic material that extends for a length L along the WP 220. The step 262 may extend from the flare point 222, to the end of the write pole 220 opposite the ABS, in some embodiments. The length L is between about 1 μm and about 15 μm. In some embodiments, the trailing step 262 of magnetic material increases the magnetic flux to the WP 220, by providing a greater thickness of the WP 220 in a direction generally parallel to the ABS and perpendicular to the width of the WP 220. In operation, write current passes through coil 218 and induces a magnetic field (shown by dashed line 228) from the WP 220 that passes through the RL 204 (to magnetize the region of the RL 204 beneath the WP 220), through the flux return path provided by the EBL 206, and back to the return pole 214.

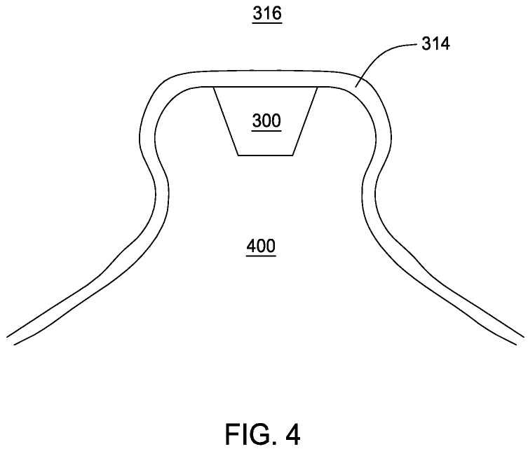

FIG. 2A also illustrates one embodiment of a magnetic shield 250 that is separated from WP 220 by a nonmagnetic gap layer 256. In some embodiments, the magnetic shield 250 may be a trailing shield wherein substantially all of the shield material is on the trailing end 203. Alternatively, in some embodiments, the magnetic shield 250 may be a wrap-around shield wherein the shield covers the trailing end 203 and also wraps around the sides of the write pole 220, as best shown in FIGS. 4-6. As FIG. 2A is a cross section through the center of the read/write head 200, it represents both trailing and wrap-around embodiments.

Near the ABS, the nonmagnetic gap layer 256 has a reduced thickness and forms a shield gap throat 258. The throat gap width is generally defined as the distance between the WP 220 and the magnetic shield 250 at the ABS. The shield 250 is formed of magnetically permeable material (such as Ni, Co and Fe alloys) and gap layer 256 is formed of nonmagnetic material (such as Ta, TaO, Ru, Rh, NiCr, SiC or Al₂O₃). A taper 260 in the gap material provides a gradual transition from the gap width at the ABS to a maximum gap width above the taper 260. This gradual transition in width, forms a tapered bump in the non-magnetic gap that allows for greater magnetic flux density from the write pole 220, while avoiding saturation of the shield 250. It should be understood that the taper 260 may extend either more or less than is shown in FIGS. 2A-2B. The taper may extend upwards to the other end of shield 250 (not shown), such that the maximum gap width is at the end of the shield opposite the ABS. The gap layer thickness increases from a first thickness (the throat gap width) at a first distance from the ABS (the throat gap height) to greater thicknesses in a direction away from the ABS, to a greatest thickness at a second distance (greater than the first distance) from the ABS. At a third distance from the ABS, greater than the second distance, the gap layer thickness is reduced in the region of the magnetic step 262.

FIG. 2B shows an enlarged side view of section 290 of FIG. 2A. Taper 260 forms angle θ relative to the ABS of the read/write head 200. In one embodiment θ is between about 20° and about 70° to the ABS of the read/write head 200, and forms a substantially fixed slope. The throat gap width is labeled as TW in FIG. 2B and is defined as the distance between the WP 220 and the magnetic shield 250 at the ABS. The taper in the gap layer 256, allows for a reduced TW without excessive fringing of the magnetic field. In one embodiment, the TW is between about 15 nm and 40 nm. The throat height TH is generally defined as the distance between the ABS and the shield height at the front edge 252 of the shield 250. In some embodiments, the TH is between about 25 nm and 125 nm. Above the TH, the width of the gap 256 increases to a maximum gap width GW along taper 260. The taper 260 extends for between 50 nm and 150 nm above the TH, depending on the TW, GW and θ. The maximum gap width GW is between 65 nm and 240 nm. The gap width is reduced to GW_{R}, in the area of the trailing step 262. GW_{R} is between 65 nm and 140 nm, in some embodiments. The transition between the front edge 252 and taper 260 may be abrupt and form a sharp corner, or may be more gradual. The transition generally has a radius of curvature R₁ as shown in FIG. 2B. In one embodiment, R₁ is between about 0 nm and about 35 nm. The greater R₁, the more gradual the transition. R₂ is shown as the radius of curvature between the taper 260 and the region 270 of maximum gap width. In one embodiment, R₂ is between 0 nm and 75 nm. It is contemplated that R₁ and R₂ may or may not be equal values in varying embodiments. By rounding these corners and providing a gradual transition, the possibility of magnetic field fringing and leakage is reduced.

FIG. 2C shows an enlarged top view of the WP 220 of FIG. 2A, with the shield layer 250 and the gap layer 256 removed to show details of the WP 220, according to another embodiment of the invention. In the illustrative embodiment, the magnetic step 262 covers part of the WP 220. The WP 220 includes flared sides 274, which extend from the flare point 222 away from the ABS, such that the main pole increases from a first thickness T₁ to greater thicknesses in a direction away from the ABS. In some embodiments, the first thickness, T₁ is between 30 nm and 150 nm. The flared sides 274 form an angle α with respect to the non-flared (substantially parallel) sides 272 of the pole tip 224. In one embodiment α is between about 30° and about 60°. The trailing step—262 has a front edge in facing relationship to the ABS that may be aligned with the flare point 222 in some embodiments, such that the magnetic step 262 extends from the flare point 222 and overlies the flared portion of the write pole 220. In this embodiment, the front edge and the flare point 222 are substantially equidistant from the ABS. By “substantially equidistant” it is meant that the front edge and the flare point 222 are the same distance from the ABS within process tolerances. In some embodiments, these two features are defined by two independent lithographic steps and the alignment is limited by the tolerances of both lithographic steps. In one embodiment, the term “substantially equidistant” is considered to mean that the front edge and the flare point 222 are the same distance from the ABS within 45 nm±. In other embodiments, the magnetic step 262 has a front edge 264 that is closer to the ABS than the flare point 222, such that part of the pole tip 224 is covered by the magnetic step 262. In further embodiments, the magnetic step 262 has a front edge 266 that is further from the ABS than the flare point 222, such that part of the flared write pole 220 is not covered by the trailing step 262. The alignment of the magnetic step front edge and the flare point 222 may be adjusted during deposition of the trailing step 262, as described below, to maximize write flux while keeping fringing and leakage to a minimum. The distance between the trailing step front edge (264 or 266) and the flare point 222, is between 0 nm (when the front edge of the trailing step and the flare point 222 are aligned with one another) and 100 nm. Thus, the distance from the trailing step front edge and the ABS is between about 75 nm and 275 nm. The desired alignment between the magnetic step front edge and the flare point 222 depends on other structural and functional limitations of the write head 210. The alignment is chosen to maximize the magnetic field produced by the head, while also suppressing stray fields.

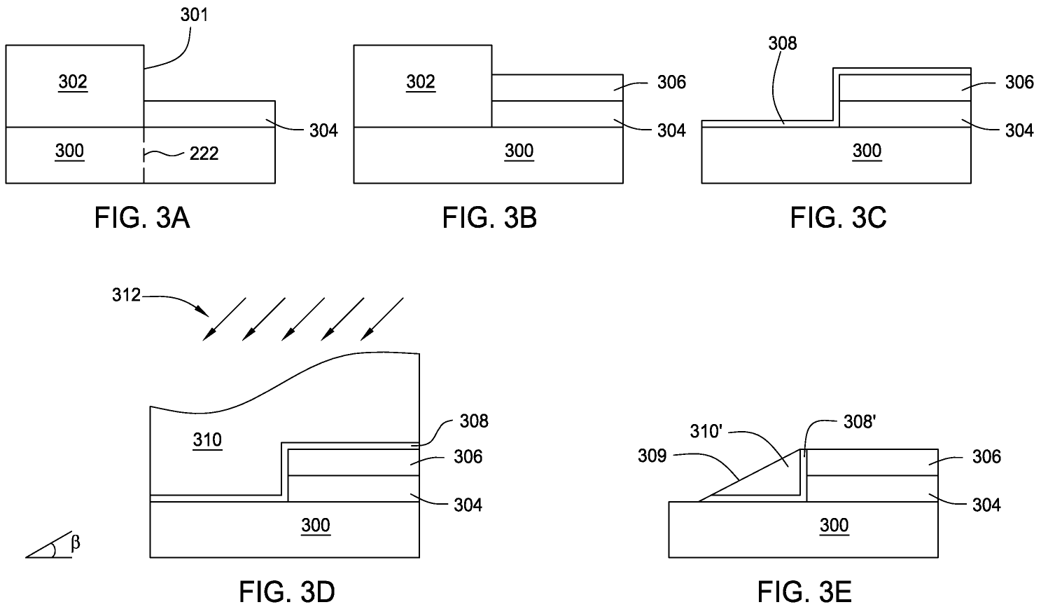

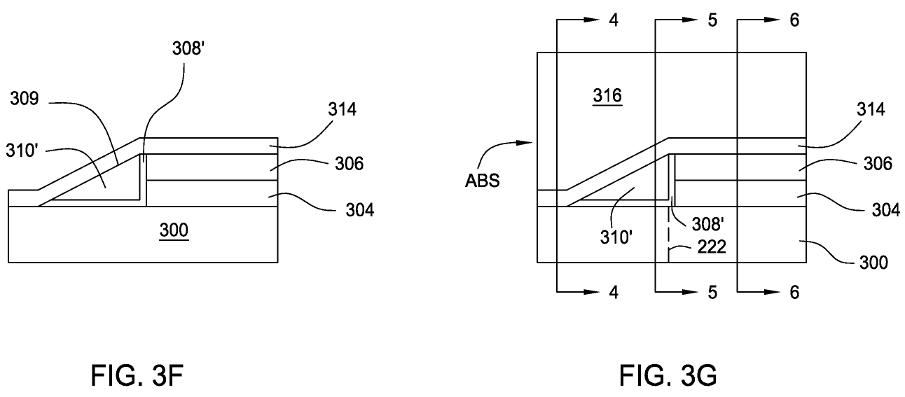

FIGS. 3A-3G illustrate one embodiment of a method for forming the magnetic write head of the invention. In FIG. 3A a substrate 300 is shown. Substrate 300 may be WP 220 of FIGS. 2A-2C, or may be a temporary substrate from which the deposited layers are transferred to WP 220. In some embodiments, the substrate 300 may be a laminated write pole and will be referred to as such for purposes of illustration. A resist layer 302 is deposited and patterned on top of write pole 300. The resist layer 302 may be formed of photoresist or other suitable materials, such as deep ultraviolet (DUV)248 nm or 193 nm lithography resist. In flared pole embodiments, when forming the resist layer 302, the edge 301 of the resist layer 302 is aligned relative to the flare point 222 of the write pole 300. This alignment determines the final alignment of the magnetic step front edge and the flare point 222 as previously described. After depositing and patterning the resist layer 302, a magnetic step 304 is plated on the exposed portions of the write pole 300, to form the trailing step of the WP 220. The magnetic step 304 is plated to a thickness of between about 50 nm and 100 nm thick, and is made of suitable magnetic material such as Ni, Co and Fe alloys. In some embodiments, the magnetic step 304 may be laminated similar to the laminated write pole of the substrate 300. FIG. 3B shows a non-magnetic step material 306 plated on top of the magnetic step 304. The non-magnetic step 306 is plated, in one embodiment, to a thickness of between about 50 nm and 100 nm, and is formed of non-magnetic material that can be plated such as NiP, Au or Cu. Continuing to FIG. 3C, the resist layer 302 is removed and an endpoint layer 308 is deposited on top of and on the sides of layers 304 and 306, and on top of the exposed portion of the write pole 300. The endpoint layer 308, in one embodiment is formed of Ta, Ti, NiCr or Ru and is deposited to a thickness of between about 2 nm and 10 nm. In one embodiment the endpoint layer 308 is deposited by sputtering, although other deposition techniques may be used. The endpoint layer 308 provides an indicator to stop the milling process as described below.

After the endpoint layer 308 is deposited, a relatively thick (about 50 nm and 200 nm) non-magnetic layer 310 is conformally deposited on top of endpoint layer 308, as shown in FIG. 3D. Non-magnetic layer 310 is formed of a non-magnetic material such as Al₂O₃ or Ru, that may, in one embodiment, be deposited using atomic layer deposition (ALD). Once the non-magnetic layer 310 is deposited, the structure is subjected to an ion beam milling process. The ion beams (shown as arrows 312) are directed at an angle β to the write pole 300, to form the taper 260 described above. In one embodiment, the angle β is between about 20° and about 50°. The ion beam milling process removes part of the endpoint layer 308 and the non-magnetic layer 310, leaving portions 308′ and 310′ and forming the angled surface 309 as shown in FIG. 3E, by shading of the ion beams by the layers 304 and 306. The term “shading” used in this context refers to the ability of the material of layers 304 and 306 (in particular 306 as the top layer) to block the ion beams from striking and removing the material of non-magnetic layer 310, in the region adjacent to layers 304 and 306 (to the left of layers 304 and 306, in FIG. 3E), thereby leaving the material in portion 310′ that forms the angled surface 309. The ion beam milling process, in one embodiment, is conducted using Ar ions and detection of the endpoint layer 308 is conducted using secondary ion mass spectroscopy (SIMS).

In FIG. 3F, a non-magnetic plating seed layer 314, is shown deposited on top of layers 306, remaining portions 308′ and 310′, and the exposed portion of write pole 300. Non-magnetic plating seed layer 314, in some embodiments, is formed of high adhesion materials such as Ta or Cr, followed by a high conductivity material such as Ru or Rh. In one embodiment, layers 306, 308′, 310′ and 314 form the non-magnetic gap layer 256 of FIGS. 2A-2B. Magnetic material (such as Ni, Co and Fe alloys) to form the magnetic shield layer 316 is then plated on non-magnetic plating seed layer 314, to complete the structure as shown in FIG. 3G. In some embodiments, magnetic shield layer 316 forms the magnetic shield 250 of FIGS. 2A-2B.

FIG. 4 is a cross section of the structure of FIG. 3G taken through section line 4-4, (close to the level of the ABS, as shown in FIGS. 2A, 2B and 3G). In FIG. 4, the write pole (layer 300) cross section, close to the ABS, is shown. As can be seen in FIG. 4, in one embodiment, the write pole 300 is trapezoidal in cross-section. In another embodiment, the write pole 300 is triangular in cross-section. The write pole 300 is surrounded below and on the sides, by non-magnetic material 400. Material 400 includes material 219 (FIG. 2A) below and on the sides of the write pole 300. Layer 314 (FIG. 3G) forms a thin non-magnetic gap layer on top of the write pole 300 and on the top and sides of material 400. Shield 316 surrounds the write pole structure and is separated from the top of the write pole 300 by a relatively thinner gap formed by the non-magnetic plating seed layer 314. Note that, in this embodiment, layers 304, 306, 308′ and 310′, are not visible as these layers do not extend to section line 4-4 in FIG. 3G.

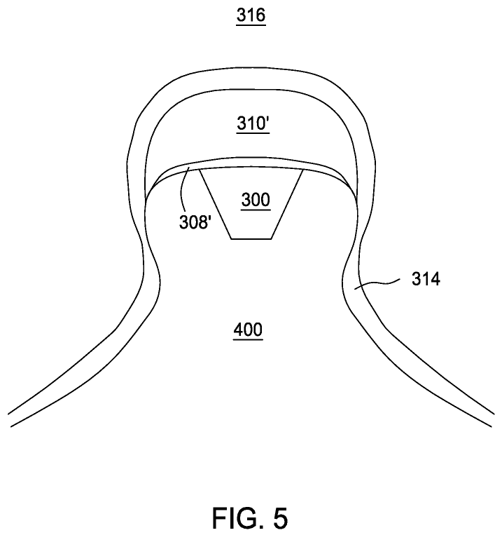

FIG. 5 is a cross section of the structure of FIG. 3G taken through section line 5-5. In FIG. 5 the write pole 300 is separated from the shield 316 by a relatively thicker gap formed of non-magnetic layers 308′, 310′ and 314 of FIG. 3G. It should be noted that the cross section of write pole 300 is substantially similar to the cross section of write pole 300 in FIG. 4, as both of these cross sections are taken to the left of the flare point 222 as shown in FIG. 3G.

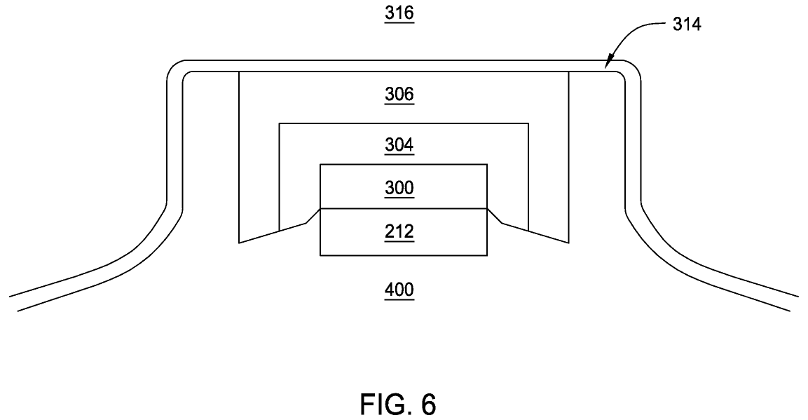

FIG. 6 is a cross section of the structure of FIG. 3G taken through section line 6-6. In FIG. 6 the cross section of write pole 300 is wider than the cross section of the write pole 300 as shown in FIGS. 4 and 5, as this cross section is taken to the right of the flare point 222 in FIG. 3G. Beneath the write pole 300 is the main pole 212, (see FIG. 2A). The main pole 212 is surrounded by non-magnetic material 400. The magnetic step 304 is disposed on the write pole 300, on the top and to the sides thereof. The non-magnetic step 306 is disposed on top of and to the sides of the magnetic step 304. The non-magnetic plating seed layer 314 covers the top and sides of non-magnetic step 306 and non-magnetic material 400. The magnetic shield 316 is shown above and to the sides of all of the layers, forming a wrap-around shield. The main pole at this cross section includes main pole 212, write pole 300 and magnetic step 304. The magnetic step 304 allows additional magnetic flux to be provided to the write pole 300, while avoiding fringing or leakage near the ABS. The main pole is separated from the shield 316 by the gap formed of the non-magnetic step 306, by the non-magnetic side gap material 400 and the non-magnetic plating seed layer 314.

While the foregoing is directed to embodiments of the present invention, other and further embodiments of the invention may be devised without departing from the basic scope thereof, and the scope thereof is determined by the claims that follow.

What is claimed is:

1. A magnetic write head for a hard disk drive, comprising:
an air bearing surface (ABS);
a magnetic write pole having an end that defines part of the ABS, the magnetic write pole including a trailing step, such that the write pole has a first thickness at the end that defines part of the ABS and a second thickness in the region of the trailing step, the second thickness being greater than the first thickness;
a layer of non-magnetic gap material disposed on the magnetic write pole, the layer of non-magnetic gap material including a taper defined by an increasing thickness of the layer of non-magnetic gap material from a third thickness at a first distance from the ABS, to a fourth thickness at a second distance from the ABS, the second distance being greater than the first distance and the fourth thickness being greater than the third thickness; and
a magnetic shield disposed on the layer of non-magnetic gap material.

2. The magnetic write head of claim 1, wherein the write pole is a flared pole having a first width at the ABS and an increasing width starting at a flare point and extending away from the ABS.

3. The magnetic write head of claim 2, wherein the flare point is between about 30 nm and about 150 nm from the ABS.

4. The magnetic write head of claim 3, wherein the trailing step has a front edge in facing relationship to the ABS, the front edge being between about 75 nm and about 275 nm from the ABS.

5. The magnetic write head of claim 4, wherein the trailing step front edge and the flare point are aligned, such that the trailing step front edge and the flare point are substantially equidistant from the ABS.

6. A hard disk drive comprising:
a magnetic storage disk; and
a magnetic write head for writing data to the disc drive, the magnetic write head comprising:
an air bearing surface (ABS);
a magnetic write pole having an end that defines part of the ABS, the magnetic write pole including a trailing step, such that the write pole has a first thickness at the end that defines part of the ABS and a second thickness in the region of the trailing step, the second thickness being greater than the first thickness;
a layer of non-magnetic gap material disposed on the magnetic write pole, the layer of non-magnetic gap material including a taper defined by an increasing thickness of the layer of non-magnetic gap material from a third thickness at a first distance from the ABS, to a fourth thickness at a second distance from the ABS, the second distance being greater than the first distance and the fourth thickness being greater than the third thickness; and
a magnetic shield disposed on the layer of non-magnetic gap material.

7. The hard disk drive of claim 6, wherein the write pole is a flared pole having a first width at the ABS and an increasing width starting at a flare point and extending away from the ABS.

8. The hard disk drive of claim 7, wherein the flare point is between about 30 nm and about 150 nm from the ABS.

9. The hard disk drive of claim 8, wherein the trailing step has a front edge in facing relationship to the ABS, the front edge being between about 75 nm and about 275 nm from the ABS.

10. The hard disk drive of claim 9, wherein the trailing step front edge and the flare point are aligned, such that the trailing step front edge and the flare point are substantially equidistant from the ABS.

11. A method of forming a magnetic write head, the method comprising:
providing a substrate, the substrate comprising a first layer of magnetic material for forming a magnetic pole of the write head, and having a surface;
depositing and patterning a resist layer on the surface of the substrate, such that a first part of the surface is covered by the resist layer and a second part of the surface is exposed;
depositing a second layer of magnetic material on the exposed part of the surface of the first layer;
depositing a third layer of non-magnetic material on the second layer of magnetic material;
removing the resist layer;
depositing a fourth endpoint layer of on the third layer and on an exposed portion of the first layer;
depositing a fifth non-magnetic layer on the fourth layer;
selectively removing part of the fifth layer to form a taper in the fifth layer, such that the fifth layer increases in thickness from a first thickness at a first distance from the ABS, to a second thickness at a second distance from the ABS, where the second thickness is greater than the first thickness and the second distance is greater than the first distance;
depositing a sixth layer of non-magnetic material on a remainder of the fifth layer; and
depositing a seventh layer of magnetic material on the sixth layer to form a magnetic shield of the write head.

12. The method of forming a magnetic write head of claim 11, wherein:
the magnetic pole is a flared magnetic pole and the magnetic pole has a flare point where a width of the magnetic pole increases from a first width to greater widths; and
the depositing and patterning the resist layer comprises aligning an edge of the resist layer relative to the flare point, to thereby align a front edge of the second layer of magnetic material relative to the flare point.

13. The method of forming a magnetic write head of claim 11, wherein selectively removing part of the fifth layer comprises subjecting the fifth layer to an ion beam milling process.

14. The method of forming a magnetic write head of claim 13, wherein the ion beam milling process comprises directing ion beams at an angle to the substrate, such that the second layer and the third layer provide shading of the ion beams to thereby form the taper in the fifth layer.

15. The method of forming a magnetic write head of claim 11, wherein the second layer of magnetic material is deposited by an electroplating process.

16. The method of forming a magnetic write head of claim 11, wherein the third layer of non-magnetic material is deposited by an electroplating process.

17. The method of forming a magnetic write head of claim 11, wherein the fourth endpoint layer is deposited by a sputtering process.

18. The method of forming a magnetic write head of claim 11, wherein the sixth layer of non-magnetic material is a plating seed layer formed of a high adhesion material, followed by a layer of high conductivity material.

19. The method of forming a magnetic write head of claim 18, wherein depositing the seventh layer of magnetic material comprises plating the seventh layer on the sixth layer.

20. A method of forming a magnetic write head, the method comprising:
providing a magnetic write pole having an end that defines part of an ABS;
forming a trailing step on the write pole to produce a stepped write pole, such that the stepped write pole has a first thickness at the end that defines part of the ABS and a second thickness in the region of the trailing step, the second thickness being greater than the first thickness;
forming a layer of non-magnetic gap material on the stepped write pole, the layer of non-magnetic gap material including a taper defined by an increasing thickness of the layer of non-magnetic gap material from a third thickness at a first distance from the ABS, to a fourth thickness at a second distance from the ABS, the second distance being greater than the first distance and the fourth thickness being greater than the third thickness; and
forming a magnetic shield on the layer of non-magnetic gap material.
